(19) United States
(12) Patent Application Publication
(10) Pub. No.: US 2016/0315171 A1
(43) Pub. Date: Oct. 27, 2016

(54) SEMICONDUCTOR DEVICE HAVING METAL GATE AND METHOD FOR MANUFACTURING SEMICONDUCTOR DEVICE HAVING METAL GATE

(71) Applicant: UNITED MICROELECTRONICS CORP., Hsin-Chu City (TW)

(72) Inventors: Yu-Hsiang Hung, Tainan City (TW); Chao-Hung Lin, Changhua County (TW); Chih-Kai Hsu, Tainan City (TW); Ssu-I Fu, Kaohsiung City (TW); Jyh-Shyang Jenq, Pingtung County (TW); Jun-Jie Wang, Changhua County (TW); En-Chiuan Liou, Tainan City (TW); Chih-Wei Yang, Kaohsiung City (TW); Chih-Sen Huang, Tainan City (TW); Ching-Wen Hung, Tainan City (TW); Hung-Chan Lin, Tainan City (TW); Yu-Hsiang Lin, New Taipei City (TW)

(21) Appl. No.: 14/727,853

(22) Filed: Jun. 1, 2015

(30) Foreign Application Priority Data
Apr. 23, 2015 (TW) 104113050

(51) Int. Cl. H01L 29/66; H01L 29/49; H01L 29/423; H01L 21/28

(52) U.S. Cl. CPC H01L 29/66545; H01L 21/28088; H01L 29/4966; H01L 29/42376

(57) ABSTRACT

A method for manufacturing a semiconductor device having a metal gate includes forming a filling layer and a high-K gate dielectric layer in the first recess between a pair of spacers, wherein the high-K gate dielectric layer and the filling layer are stacked in the first recess sequentially, and an exposed top surface of the high-K gate dielectric layer and a top surface of the filling layer are lower than a top surface of each spacer; and removing a part of each spacer and widening the first recess on the top surface of the filling layer to form a second recess, wherein a width of the second recess is larger than a width of the first recess.

### BACKGROUND OF THE INVENTION

1. Field of the Invention

The present invention relates to a semiconductor device having a metal gate and a method for manufacturing the semiconductor device having the metal gate, and more particularly, to a manufacturing method forming a high dielectric constant gate dielectric layer after widening a recess and a semiconductor device formed by using the manufacturing method.

2. Description of the Prior Art

With a trend toward scaling down the size of the semiconductor device, the width of the gate structure is shrunk. Accordingly, a resistance of the gate is decreased, thereby affecting the operation of the semiconductor device. For maintaining the low resistance of the gate or even reducing the resistance of the gate, work function metals are used to replace the conventional polysilicon gate to be the gate which is so called the metal gate.

In the conventional replacement metal gate (RMG) method, a dummy gate is formed first. After the manufacture of the general MOS transistor is completed, the dummy gate is removed to form a gate trench and followed by filling the gate trench with the work function metals. In particularly, in order to achieve different requirements in electricity, transistors with different functions and different conductive types need to fill different work function metals or work function metals with different thicknesses. With this arrangement, multilayer work function metals need to be deposited in the gate trench.

It should be noted that when the width of the gate trench is shrunk with the minimization of the semiconductor device, poor filling is easily generated, which results in an issue of voids, in the process for forming the metal gate. Also, the gate trench not only is filled with the work function metals, but also is filled with layers, such as the high-K dielectric layer and the barrier metal. Thus, the ability to fill the gate trench with the layers is further limited, and a device failure problem easily occurs. For this reason, it is more difficult to manufacture a desirable metal gate when the size of the semiconductor device keeps scaling down.

### SUMMARY OF THE INVENTION

It is therefore a purpose of the present invention to provide a semiconductor device having a metal gate and a method for manufacturing the semiconductor device having the metal gate, which raises the ability to form the metal gate in the gate trench through widening the gate trench so as to form a preferred and completed metal gate.

For achieving the above-mentioned purpose, the present invention provides a method for manufacturing a semiconductor device having a metal gate. First, a substrate, a pair of spacers and an interlayer dielectric layer are provided, wherein the spacers and the interlayer dielectric layer are formed on the substrate, the interlayer dielectric layer surrounds the spacers, and the spacers have a first recess therebetween. Then, a filling layer and a high-K gate dielectric layer are formed in the first recess, wherein the high-K gate dielectric layer and the filling layer are sequentially stacked in the first recess, and an exposed top surface of the high-K gate dielectric layer and a top surface of the filling layer are lower than a top surface of the interlayer dielectric layer. Next, a first removing process is performed to remove a part of each spacer disposed on the top surface of the filling layer and widen the first recess on the top surface of the filling layer so as to form a second recess, wherein a width of the second recess is larger than a width of the first recess.

For achieving the above-mentioned purpose, the present invention further provides a semiconductor device having a metal gate including a substrate, a pair of spacers, a high-K gate dielectric layer, a metal gate, an insulating cover layer, and an interlayer dielectric layer. The spacers are disposed on the substrate, and each spacer has a wide part and a narrow part on the wide part, wherein a gap spaced between the narrow parts is larger than a gap spaced between the wide parts. The high-K gate dielectric layer, disposed on the substrate and between the spacers. The metal gate is disposed on the high-K gate dielectric layer, and the metal gate includes a metal layer, wherein the metal layer has a U-shaped part and two flat parts, the U-shaped part is disposed between the wide parts, the flat parts are disposed on the wide parts and between the narrow parts, and the flat parts extend form two ends of the U-shaped part to be in contact with the narrow parts respectively. The insulating cover layer is disposed on the metal gate. The interlayer dielectric layer is disposed on the substrate, and the interlayer dielectric layer surrounds the metal gate, the spacers and the insulating cover layer.

In the method for manufacturing the semiconductor device having the metal gate provided by the present invention, the filling layer is used to shield the layers in the first recess, so that the unwanted layers can be removed. And the first recess on the filling layer is widened when the first recess is filled with the filling layer, such that the following steps for filling the layers into the first recess will not result in the bad filling problem.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-9, which are schematic diagrams illustrating a method for manufacturing a semiconductor device having a metal gate according to a first embodiment of the present invention.

FIGS. 10-12, which are schematic diagrams illustrating a method for manufacturing a semiconductor device having a metal gate according to a second embodiment of the present invention.

FIGS. 13-15, which are schematic diagrams illustrating a method for manufacturing a semiconductor device having a metal gate according to a third embodiment of the present invention.

FIGS. 16-18, which are schematic diagrams illustrating a method for manufacturing a semiconductor device having a metal gate according to a fourth embodiment of the present invention.

FIGS. 19-21, which are schematic diagrams illustrating a method for manufacturing a semiconductor device having a metal gate according to a fifth embodiment of the present invention.

FIG. 22, which is a schematic diagram illustrating a method for manufacturing a semiconductor device having a metal gate according to a sixth embodiment of the present invention.

### DETAILED DESCRIPTION

Refer to FIGS. 1-9, which are schematic diagrams illustrating a method for manufacturing a semiconductor device having a metal gate according to a first embodiment of the present invention. In this embodiment, the semiconductor device for example includes a p-type transistor and an n-type transistor, but the present invention is not limited herein. In other embodiments, the semiconductor device may include a plurality of transistors with a same conductive type but different functions or a plurality of transistors with different conductive types. As shown in FIG. 1, a substrate 100, two dummy gates 102, two pairs of spacers 104 and an interlayer dielectric layer (hereinafter abbreviated as ILD) 106 is provided first. The substrate 100 may have a p-type transistor region 100a and an n-type transistor region 100b defined thereon, but the present invention is not limited herein. The p-type transistor region and the n-type transistor region may be exchanged. The substrate 100 may be a semiconductor substrate, such as a silicon substrate, a substrate including silicon, or a silicon-on-insulator (hereinafter abbreviated as SOI). In the substrate 100, a plurality of shallow trench isolations (STI) (not shown) may be formed to electrically insulate different transistors from each other. In this embodiment, the substrate 100 may include a fin structure of a fin field effect transistor (hereinafter abbreviated as FINFET) (not shown). The fin structure can be formed by patterning a bulk silicon substrate or a single crystalline silicon layer of a SOI substrate through a photolithographic etching pattern (PEP) method, a multi patterning method, or, preferably, a spacer self-aligned double-patterning (SADP), also known as sidewall image transfer (SIT) method. Thus, a silicon thin film with a fin shape is formed in the bulk silicon substrate or the SOI substrate.

In this embodiment, the dummy gates 102 may be for example a polysilicon layer or an amorphous silicon layer and can be defined by a first hard mask layer 108 disposed on the dummy gate and formed on the substrate 100 through the shielding of the first hard mask layer 108. Then, each pair of spacers 104 are formed on sidewalls of each dummy gate 102 respectively and followed by forming sources and drains (not shown), such as p-type doped regions or n-type doped regions, in the fin structure uncovered with the dummy gates 102. The conductive types of the doped regions are determined by the types of the transistors. In other embodiments, the sources or drains may be a p-type epitaxial layer or an n-type epitaxial layer. Subsequently, a contact etch stop layer (hereinafter abbreviated as CESL) 110 and the ILD layer 106 are sequentially formed to cover the substrate 100, the dummy gates 102 and the spacers 104 and followed by performing a planarization process, such as chemical mechanical polishing (CMP) process, to planarize the ILD layer 106 and the CESL 110, such that the first hard mask layer 108 is exposed. Accordingly, the spacers 104 and the ILD layer 106 may be formed on the substrate 100, in which a top surface of the ILD layer 106 is leveled with a top surface of the dummy gate 102 and top surfaces of the spacers 104, and the ILD layer 106 surrounds the spacers 104 and the dummy gate 102. In another variant, the planarization process may be performed to remove the first hard mask layer 108 to expose the dummy gate.

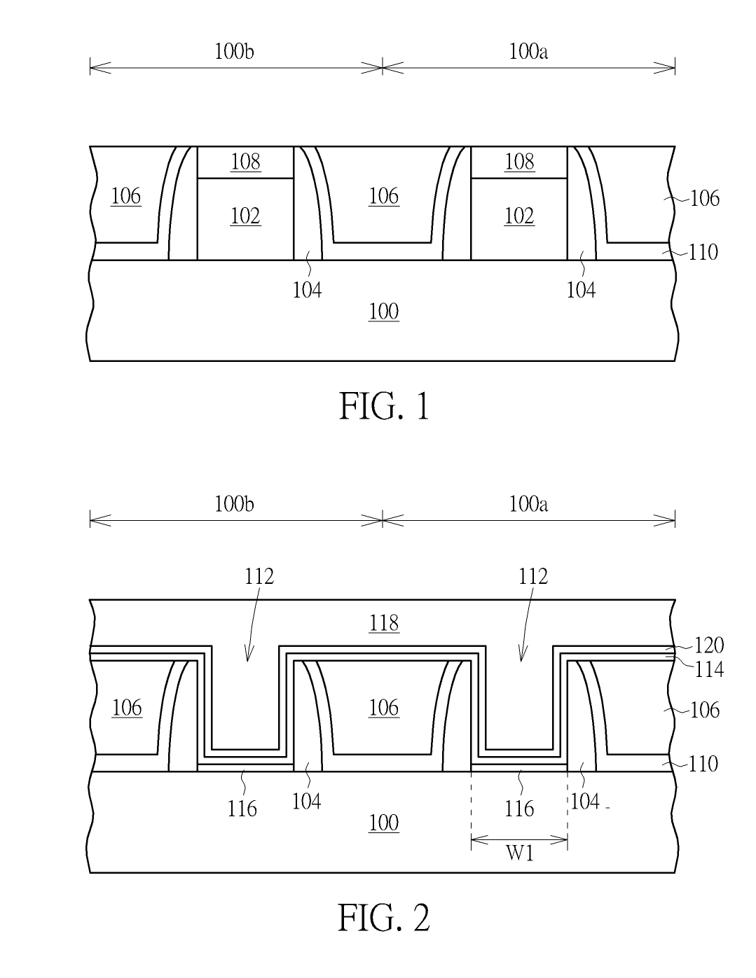

As shown in FIG. 2, following the planarization process, the first hard mask layer 108 and the dummy gates 102 are removed to form a first recess 112 between each pair of spacers 104 and followed by forming a high dielectric constant (hereinafter abbreviated as high-K) dielectric layer 114 on a surface of each first recess 112, the top surfaces of the spacers 104 and the top surface of the ILD layer 106. The high-K dielectric layer 114 is used to replace the conventional silicon oxide layer or silicon oxynitride layer to be the gate dielectric layer for decreasing physical limit thickness, reducing leakage current, and obtaining equivalent capacitor for controlling the switch of the channel in an identical equivalent oxide thickness (EOT). The high-K dielectric layer 114 can include a high-k material selected from the group consisting of silicon nitride (SiN), silicon oxynitride (SiON) and metal oxide. And the metal oxide can include hafnium oxide (HfO), hafnium silicon oxide (HfSiO), hafnium silicon oxynitride (HfSiON), aluminum oxide (AlO), lanthanum oxide (LaO), lanthanum aluminum oxide (LaAlO), tantalum oxide (TaO), zirconium oxide (ZrO), strontium zirconium silicon oxide (ZrSiO), or hafnium zirconium oxide (HfZrO), but not limited to this. In this embodiment, an oxide layer 116 may be selectively formed on the exposed substrate 100 before forming the high-K dielectric layer 114, but not limited to this.

It should be noted that a width of each first recess 112 is larger than a thickness of the high-K dielectric layer 114, so that the high-K dielectric layer 114 can conformally cover the surfaces of the first recesses 112. For instance, the width of each first recess 112 may be substantially 20 nanometers (hereinafter abbreviated as nm), and the thickness of the high-K dielectric layer 114 may be substantially 10 angstroms (hereinafter abbreviated as A).

In this embodiment, at least one bottom barrier metal material layer 120 may be further formed between the step of forming the high-K dielectric layer 114 and the step of forming a sacrificial layer 118 selectively. For instance, the bottom barrier metal material layer 120 can be formed by a stack of titanium nitride (TiN) and tantalum nitride (TaN), but is not limited to this. The structure and the physical characteristic of the following high-K gate dielectric layers 114a can be prevented from damage in the following deposition processes and etching processes performed after forming the bottom barrier metal material layer 120 though the disposition of the bottom barrier metal layers 120a formed by the bottom barrier metal material layer 120. Since the thickness of the bottom barrier metal material layer 120 is substantially the same as the thickness of the high-K dielectric layer 114, the problem of voids are not easily generated when each first recess 112 is filled with the bottom barrier metal material layer 120.

After forming the high-K dielectric layer 114, the sacrificial layer 118 is formed on the high-K dielectric layer 114, such that the sacrificial layer 118 fills up each first recess 12 and covers a top surface of the high-K dielectric layer 114 outside each first recess 112. The material of the sacrificial layer 118 may include antireflective material, insulating material or a material with high etching selectivity ratio with respect to the high-K dielectric layer 114 and the bottom barrier metal material layer 120.

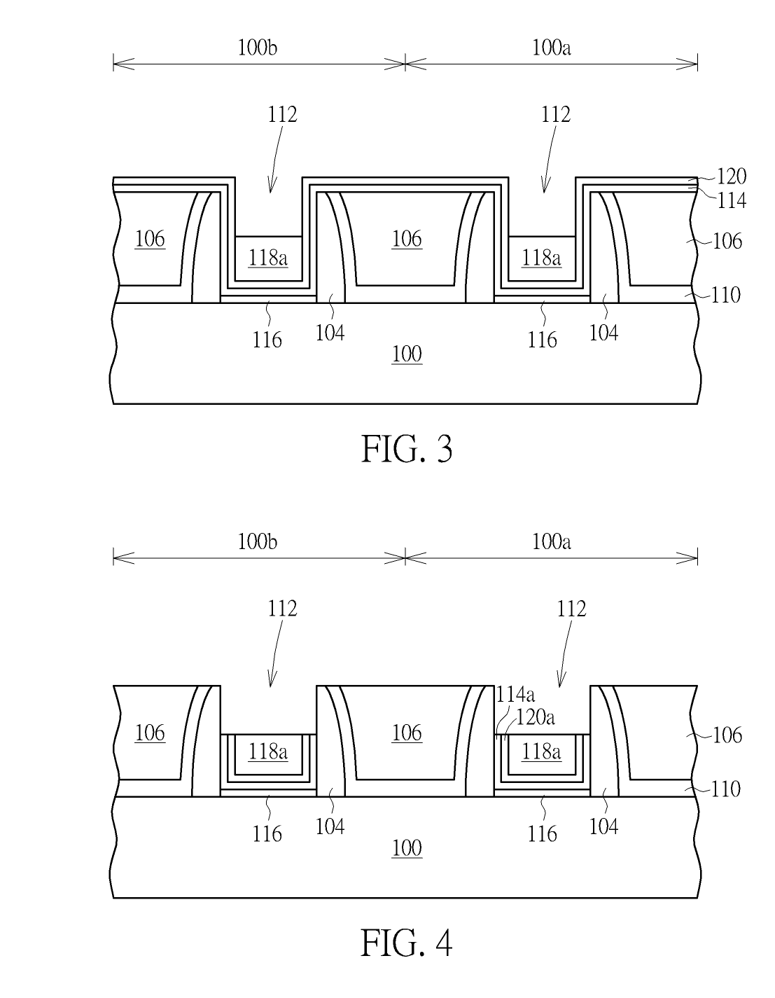

As shown in FIG. 3, after forming the sacrificial layer 118, a second removing process is performed. Since a rate of the second removing process etching the sacrificial layer 118 is faster than a rate of the second removing process etching the high-K dielectric layer 114 and the bottom barrier metal material layer 120, the sacrificial layer 118 outside each first recess 112 and a part of the sacrificial layer 118 in each first recess 112 can be removed to form a first filling layer 118a in each first recess 112. In this situation, a top surface of each first filling layer 118a is lower than the top surface of each spacer 104, which is also lower than the top surface of the ILD layer 106.

As shown in FIG. 4, after forming each first filling layer 118a, a removing process may be selectively performed to remove the bottom barrier metal material layer 120 on each first filling layer 118a, thereby forming the bottom barrier metal layer 120a in each first recess 112. After that, a third removing process is performed. Since a rate of the third removing process etching the high-K dielectric layer 114 is faster than a rate of the third removing process etching each first filling layer 118a, the high-K dielectric layer 114 on the top surface of each first filling layer 118a can be removed to form a high-K gate dielectric layer 114a in each first recess 112. Accordingly, each high-K gate dielectric layer 114a, each bottom barrier metal layer 120a and each first filling layer 118a are sequentially stacked in each first recess 112, and an exposed top surface of each high-K gate dielectric layer 114a, an exposed top surface of each bottom barrier metal layer 120a and the top surface of each first filling layer 118a are lower than the top surface of the ILD layer 106. Preferably, each high-K gate dielectric layer 114a and each bottom barrier metal layer 120a may be a like U-shaped structure, and a recess of each U-shaped structure is filled up with each first filling layer 118a, such that the exposed top surface of each high-K gate dielectric layer 114a and the top surface of each first filling layer 118a are disposed in a same plane. Besides, each bottom barrier metal layer 120a disposed between each high-K gate dielectric layer 114a and each first filling layer 118a may be a multilayer structure.

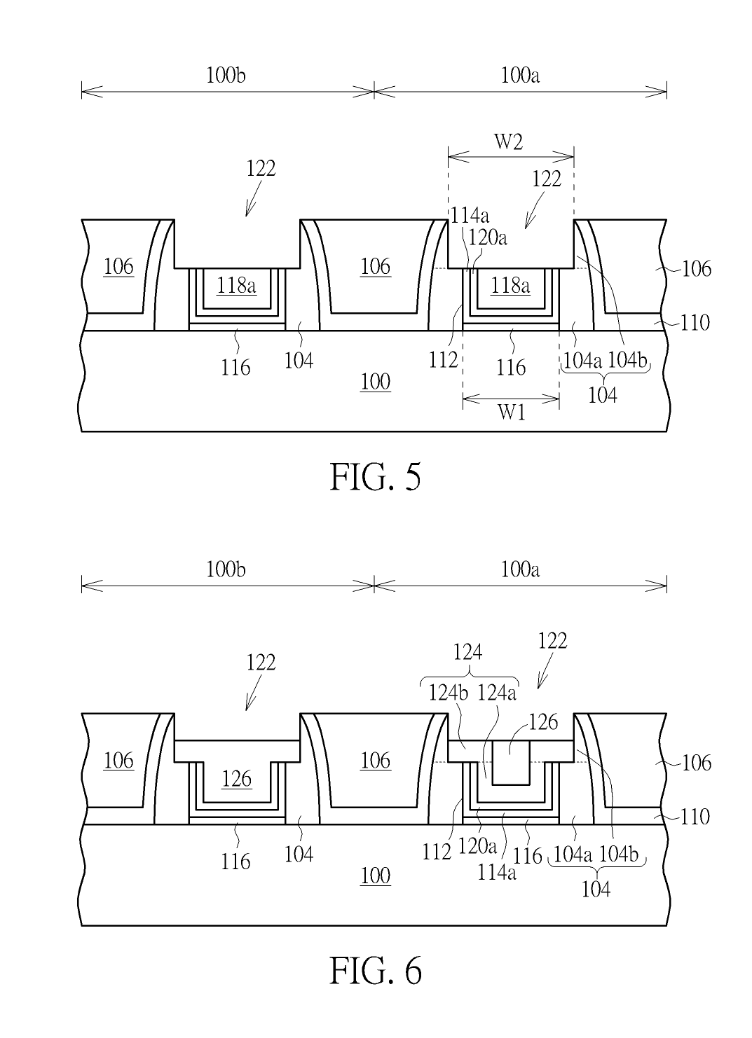

As shown in FIG. 5, a first removing process is performed subsequently. Since a rate of the first removing process etching the spacers 104 is faster than a rate of the first removing process etching the high-K gate dielectric layers 114a, the bottom barrier metal layers 120a and the first filling layers 118a, a part of each spacer 104 on the top surface of each first filling layer 118a can be removed to widen each first recess 112 on the top surface of each first filling layer 118a and to form a second recess 122 on each first filling layer 118a, such that a width W2 of each second recess 122 is larger than a width W1 of each first recess 112. For instance, a difference between the width W2 of each second recess 122 and the width W1 of each first recess 112 may be substantially 15-30 nm. It should be noted that a part of each spacer 104 on the top surface of each first filling layer 118a remains instead of being fully removed to expose the CESL 110 in the first removing process. Thus, each spacer 104 can have a wide part 104a and a narrow part 104b, in which a width of each narrow part 104b is less than a width of each wide part 104a, and each narrow part 104b is disposed on each wide part 104a, so that a step layout is formed in each second recess 122. In each pair of spacers 104, a gap spaced between the wide parts 104a is the width W1 of each first recess 112, and a gap spaced between the narrow parts 104b is the width W2 of each second recess 122. In this embodiment, since the second recesses 122 are formed after forming the high-K gate dielectric layer 114a, each high-K gate dielectric layer 114a and each bottom barrier metal layer 120a are not in contact with each narrow part 104b.

As shown in FIG. 6, after forming each second recess 122, a fourth removing process is performed to remove each first filling layer 118a and followed by forming a first work function metal layer 124 in the second recess 122 and the first recess 112 under the second recess 122 in the p-type transistor region 100a. In this embodiment, the first work function metal layer 124 may be a single-layer or multilayer structure and include a metal which work function complies with the requirement of the p-type transistor. For example, the metal may be titanium nitride (TiN), titanium carbide (TiC), tantalum nitride (TaN), tantalum carbide (TaC), tungsten carbide (WC), or aluminum titanium nitride (TiAlN).

In this embodiment, a method for forming the first work function metal layer 124 in the second recess 122 and the first recess 112 under the second recess 122 in the p-type transistor region 100a may be performed in the following steps, but is not limited to this. First, a first work function metal material layer (not shown) is conformally formed to cover each second recess 122, each first recess 112 under each second recess 122 and the ILD layer 106 and followed by performing a photolithographic process and an etching process to remove the first work function metal material layer in the n-type transistor region 100b. Next, a second filling layer 126 is formed on the high-K gate dielectric layer 114a and the bottom barrier metal layer 120a in the n-type transistor region 100b and on the first work function metal material layer in the p-type transistor region 100a and can be used to protect the high-K gate dielectric layers 114a, the bottom barrier metal layers 120a and a part of the first work function metal material layer while removing the unwanted first work function metal material layer. Since a top surface of the second filling layer 126 is lower than the top surface of the ILD layer 106, the first work function metal material layer outside the second recesses 122 and on the top surface of the second filling layer 126 can be removed subsequently to form the first work function metal layer 124 in the p-type transistor region 100a. In this embodiment, since the first work function metal layer 124 is formed after widening the first recesses 112, the first work function metal layer 124 in the second recess 122 of the p-type transistor region 100a may have a U-shaped part 124a and two flat parts 124b, which forms a like inverse Ω shape. The U-shaped part 124a is disposed between the wide parts 104a in the p-type transistor region 100a, and the flat parts 124b are disposed on the wide parts 104a and between the narrow parts 104b and extend from two ends of the U-shaped part 124a to be in contact with the narrow parts 104b along top surfaces of the wide parts 104a respectively.

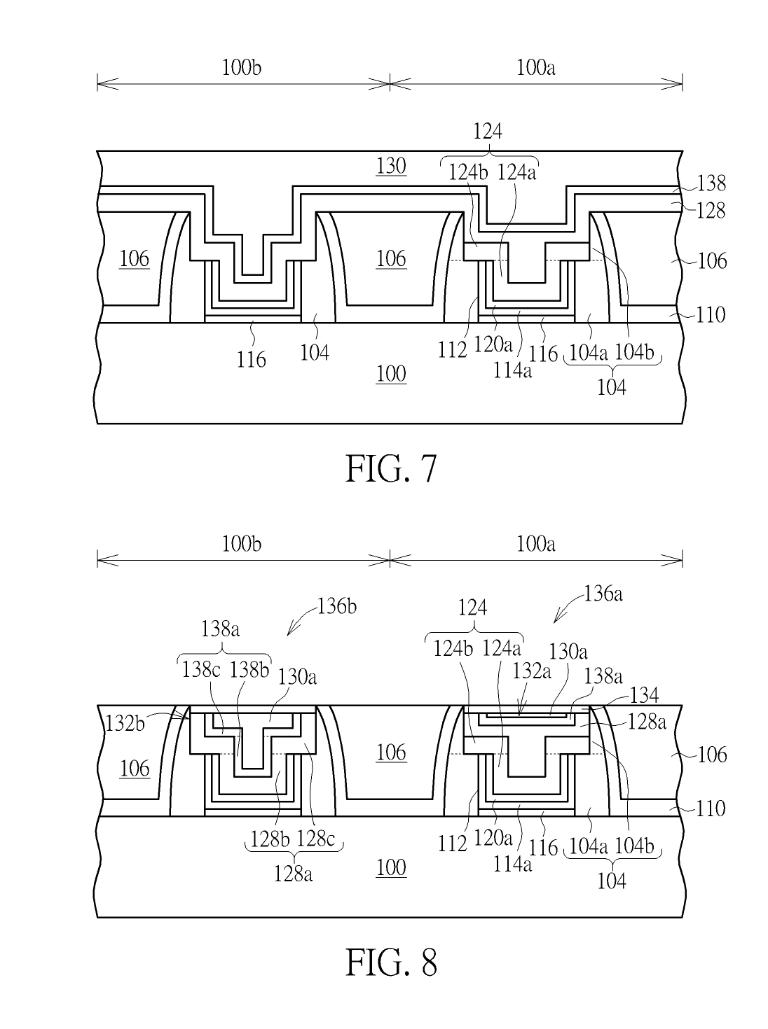

As shown in FIG. 7, after forming the first work function metal layer 124, each second filling layer 126 is removed first and followed by forming a second work function metal material layer 128 in the second recess 122 and the first recess 112 under the second recess 122 in the n-type transistor region 100b and on the first work function metal layer 124 in the p-type transistor region 100a. Next, each second recess 122 and each first recess 112 under each second recess 122 are filled up with a filling metal material layer 130. The second work function metal material layer 128 may include a metal which work function complies with the requirement of the n-type transistor. For example, the metal may be aluminum titanium (TiAl), aluminum zirconium (ZrAl), aluminum tungsten (WAl), aluminum tantalum (TaAl) or aluminum hafnium (HFAl). The filling metal material layer 130 may be a single-layer metal layer or composite metal layer with preferred ability to be filled into holes, which include aluminum (Al), titanium (Ti), tantalum (Ta), tungsten (W), niobium (Nb), molybdenum (Mo), copper (Cu), titanium nitride (TiN), titanium carbide (TiC), tantalum nitride (TaN), titanium tungsten (Ti/W) or titanium and titanium nitride (Ti/TiN), but is not limited to this. As compared with the thicknesses of the high-K dielectric layer 114 and the bottom barrier metal material layer 120, twice of a sum of the thickness of the first work function metal material layer 124 and the thickness of the second work function metal material layer 128 is close to the width W1 of each first recess 112, and the thickness of the first work function metal material layer 124 and the thickness of the second work function metal material layer 128 may be substantially 20-60 Å respectively.

In this embodiment, at least one top barrier metal material layer 138 may be selectively further formed between the step of forming the second work function metal material layer 128 and the step of forming the filling metal material layer 130 to avoid the filling metal material layer 130 affecting the physical characteristics of the first work function metal layer 124 and the second work function metal material layer 128.

As shown in FIG. 8, subsequently, a planarization process is performed to remove the unwanted second work function metal material layer 128, the unwanted top barrier metal material layer 138 and the unwanted filling metal material layer 130 outside each second recess 122 and followed by performing a metal etching process to remove a part of the second work function metal material layer 128, a part of the top barrier metal material layer 138 and a part of the filling metal material layer 130 in each second recess 122, thereby forming the second work function metal layers 128a, the top barrier metal layers 138a and the filling metal layers 130a respectively. Accordingly, a first metal gate 132a is formed in the second recess 122 and the first recess 112 under the second recess 122 in the p-type transistor region 100a, and a second metal gate 132b is formed in the second recess 122 and the first recess 112 under the second recess 122 in the n-type transistor region 100b. In the p-type transistor 100a, since the first recess 112 under the second recess 122 already is filled with the first work function metal layer 124, the second work function metal layer 128a fills up the first recess 112 under the second recess 122 and has a T-shaped part, but is not limited to this. Whether the first recess under the second recess is filled up with the second work function metal layer in the p-type transistor region 100a may be determined according to the width of the first recess. Each top barrier metal layer 138a is disposed between each second work function metal layer 128a and each filling metal layer 130a. In another variant, the first work function metal layer may also include the metal which work function complies with the requirement of the n-type transistor, and the second work function metal layer may also include the metal which work function complies with the requirement of the p-type transistor. In this situation, the second work function metal layer on the first work function metal layer should be removed.

After forming the first metal gate 132a and the second metal gate 132b, two insulating cover layers 134 are formed on the first metal gate 132a and the second metal gate 132 in the second recesses 122 respectively. Until now, the p-type transistor 136a and the n-type transistor 136b of this embodiment are completed. Preferably, each insulating cover layer 134 may fill up each second recess 122, and a top surface of each insulating cover layer 134 and the top surface of the ILD layer 106 may be disposed in a same plane. The materials of the insulating cover layers 134 may include silicon nitride, and the insulating cover layers 134 are used to stop the etching solution for forming contact plug openings in the following processes.

Additionally, in the n-type transistor 136b of this embodiment, since the second recess 122 and the first recess 112 thereunder in the n-type transistor region 100b are not filled with the first work function metal layer 124 after removing the first filling layers 118a, the second work function metal layer 128a and the top barrier metal layer 138a formed in the n-type transistor region 100b also have a like inverse Ω-shaped part respectively. Specifically, the second work function metal layer 128a may has a U-shaped part 128b and two flat parts 128c, which forms a like inverse Ω shape. In the n-type transistor region 100b, the U-shaped part 128b is disposed between the wide parts 104a, and the flat parts 128c are disposed on the wide parts 104a and between the narrow parts 104b and extend from two ends of the U-shaped part 128b to be in contact with the narrow parts 104b in the n-type transistor region 100b respectively. Similarly, the top barrier metal layer 138a also can have a U-shaped part 138b and two flat parts 138c that form a like inverse Ω shape.

It should be noted that since the thickness of the first work function metal material layer and the thickness of the second work function metal material layer 128 are thicker as compared with the bottom and top barrier metal material layer 120, 138 and the high-K dielectric layer 114, the voids easily occur while forming the first work function metal material layer or forming the second work function metal material layer 128. Especially, the first recess 112 in the p-type transistor region 100a needs to be filled with the first work function metal layer 124 and the second work function metal layer 128a together. For this reason, each first recess 112 is widened to be each second recess 122, and at least a part of the first work function metal material layer in the second recesses 122 is removed in this embodiment, such that the width of recess that can be filled is prevented from reduction resulted from the formation of the first work function metal layer 124. Accordingly, the formed metal layers, such as the second work function metal material layer 128 and the top barrier metal layers 138a, following the formation of the second recesses 122 still can be formed well in the second recesses 122 with the width W2, and no bad filling problem occurs.

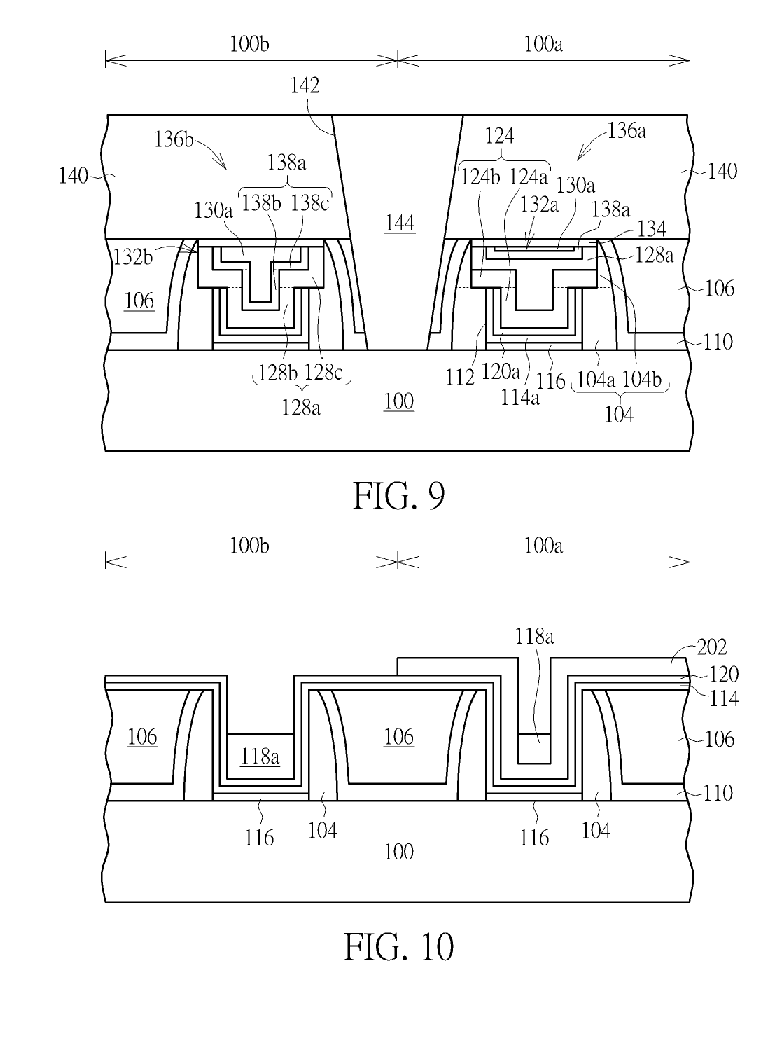

As shown in FIG. 9, after forming the insulating cover layers 134, an insulating layer 140 may be formed to cover the ILD layer 106, the CESL 110 and the insulating cover layers 134 and followed by forming at least one contact plug opening 142 in the insulating layer 140 and the ILD layer 106 and filling the contact plug opening 142 with a contact plug 144. It should be noted that instead of fully removing the spacers 104 on each first filling layer 118a to expose the CESL 110, the narrow part 104b of each spacer 104 remains in the first removing process, such that the insulating cover layers 134 not only cover the first metal gate 132a and the second metal gate 132b respectively but also contact the narrow parts 104b respectively. Accordingly, the CESL 110, the insulating cover layers 134 and the spacers 104 can surround and protect the first metal gate 132a and the second metal gate 132b. For this reason, when an error of misalignment occurs during forming the contact plug opening 142, the first metal gate 132a and the second metal gate 132b still can be protected by the CESL 110, the insulating cover layers 134 and the spacers 104, and will not be exposed in the contact plug opening 142, thereby solving a problem of gate to contact short (GC short) that results from the first metal gate 132a or the second metal gate 132b contacting the contact plug 144.

The semiconductor device having the metal gate and the method for manufacturing the same of the present invention is not limited to the above-mentioned embodiment. The following description continues to detail the other embodiments or variants, and in order to simplify and show the difference between the other embodiments or variants and the above-mentioned embodiment, the same numerals denote the same components in the following description, and the same parts are not detailed redundantly.

Refer to FIGS. 10-12, which are schematic diagrams illustrating a method for manufacturing a semiconductor device having a metal gate according to a second embodiment of the present invention. The difference between this embodiment and the first embodiment is that each first recess 112 is widened to be each second recess 122 after forming the first work function metal layer 202a in this embodiment. As shown in FIG. 10, the step of forming the first recesses 112 and the steps before it in this embodiment are the same as the first embodiment, and will not be detailed redundantly. After forming the first recesses 112, the high-K dielectric layer 114, the bottom barrier metal material layer 120 and the first work function metal material layer 202 are sequentially formed in the first recesses 112 and on the ILD layer 106. Then, the first work function metal material layer 202 in the n-type transistor region 100b is removed.

As shown in FIG. 11, subsequently, the sacrificial layer 118 is formed on the bottom barrier metal material layer 120 in the n-type transistor region 100b and the first work function metal material layer 202 in the p-type transistor region 100a and followed by removing the sacrificial layer 118 outside each first recess 112 and a part of the sacrificial layer 118 in each first recess 112 through the second removing process to form a first filling layer 118a in each first recess 112. Then, the first work function metal material layer 202 on the top surface of each first filling layer 118a is removed to form a first work function metal layer 202a in the first recess 112 in the p-type transistor region 100a. Thereafter, the unwanted bottom barrier metal material layer 120 and the unwanted high-K dielectric layer 114 are removed to form the bottom barrier metal layers 120a and the high-K gate dielectric layers 114a. Later, the first removing process is performed to widen each first recess 112 on the top surface of each first filling layer 118a to be a second recess 122, such that each spacer 104 has a wide part 104a and a narrow part 104b. Each narrow part 104b is disposed on each wide part 104a, and each spacer 104 in each second recess 122 forms a step layout. Since the second recesses 122 are formed after the first work function metal layer 202a, each high-K gate dielectric layer 114a, each bottom barrier metal layer 120a and the first work function metal layer 202a are not in contact with each narrow part 104b.

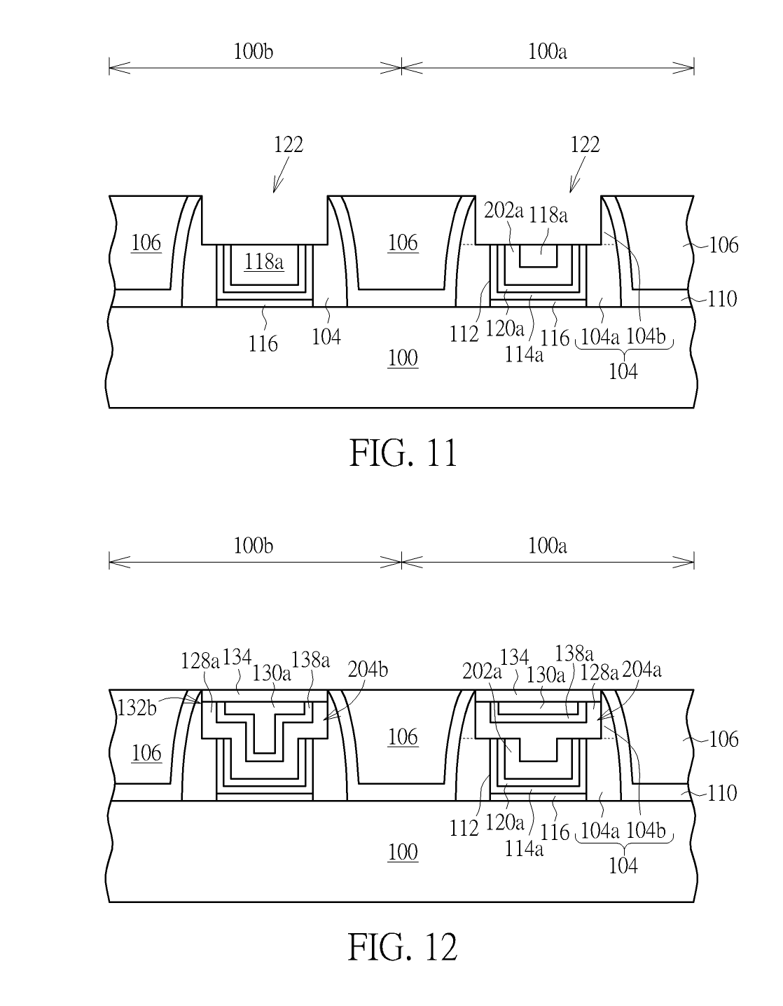

As shown in FIG. 12, each first filling layer 118a is removed subsequently. Then, the second function metal material layer (not shown), the top barrier metal material layer (not shown) and the filling metal material layer (not shown) are sequentially formed in the second recesses 122 and the first recesses 112 under the second recesses 122. Thereafter, a planarization process and a metal etching process are performed to form each second work function metal layer 128a, each top barrier metal layer 138a and each filling metal layer 130a in each second recess 122 and each first recess 112 under each second recess 122, thereby forming the first metal gate 204a and the second metal gate 204b. A top surface of the first metal gate 204a and a top surface of the second metal gate 204b are lower than a top surface of the ILD layer 106. Next, each insulating cover layer 134 is formed in each second recess 122. Moreover, the following steps of this embodiment for forming the insulating layer 140, the contact plug opening 142 and the contact plug 144 are the same as the first embodiment, and will not be detailed redundantly.

Refer to FIGS. 13-15, which are schematic diagrams illustrating a method for manufacturing a semiconductor device having a metal gate according to a third embodiment of the present invention. The difference between this embodiment and the second embodiment is that each first recess 112 is widened to be each second recess 122 after forming the second work function metal layers 302a in this embodiment. As shown in FIG. 13, the step of forming the first work function metal layer 202a and the steps before it in this embodiment are the same as the second embodiment, and will not be detailed redundantly. After forming the first work function metal layer 202a, a second work function metal material layer 302 is formed on the high-K dielectric layer 114 and the first work function metal layer 202a and followed by forming the sacrificial layer (not shown) on the second work function metal material layer 302. Then, the sacrificial layer outside each first recess 112 and a part of the sacrificial layer in each first recess 112 are removed through the second removing process to form each first filling layer 118a in each first recess 112.

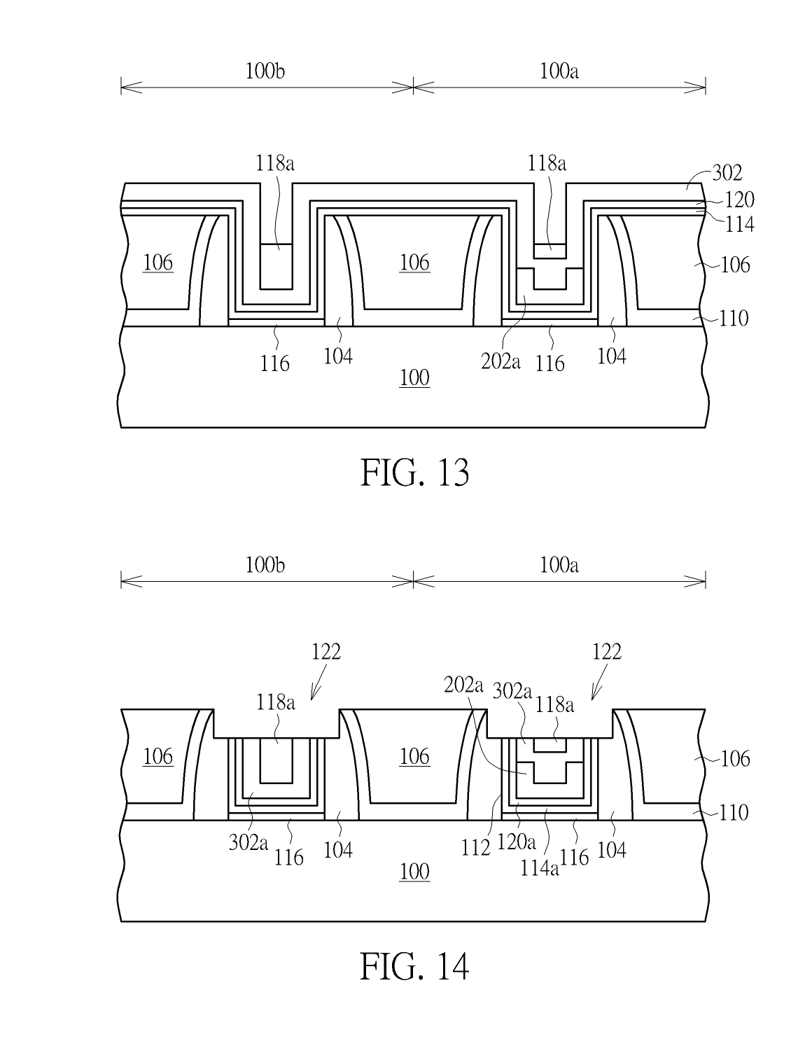

As shown in FIG. 14, after forming the first filling layers 118a, the second work function metal material layer 302 on the top surface of each first filling layer 118a is removed to form a second work function metal layer 302a in each first recess 112. Next, the bottom barrier metal material layer 120 and the high-K dielectric layer 114 disposed on the top surface of each first filling layer 118a are removed to form the bottom barrier metal layers 120a and the high-K gate dielectric layers 114a and followed by performing the first removing process to widen each first recess 112 on the top surface of each first filling layer 118a to be a second recess 122, such that each spacer 104 has a wide part 104a and a narrow part 104b. Each narrow part 104b is disposed on each wide part 104a, and each spacer 104 in each second recess 122 forms a step layout. Since the second recesses 122 are formed after the second work function metal layers 302a, each high-K gate dielectric layer 114a, each bottom barrier metal layer 120a, the first work function metal layer 202a and each second work function metal layer 302a are not in contact with each narrow part 104b.

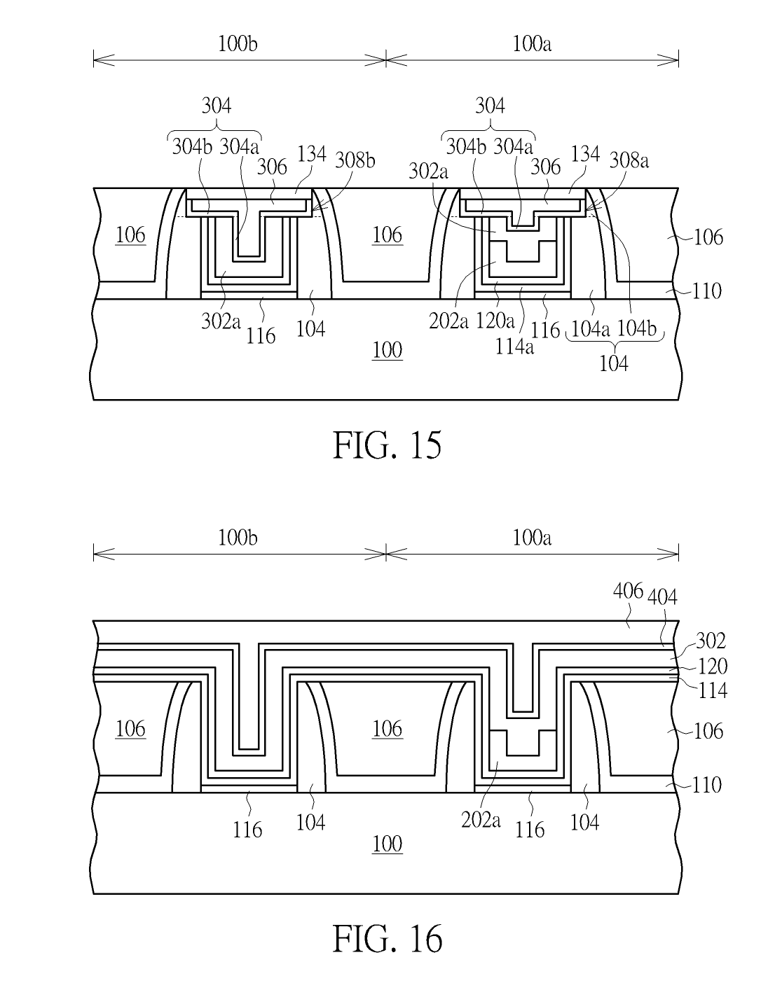

As shown in FIG. 15, each first filling layer 118a is removed subsequently and followed by sequentially forming the top barrier metal material layer (not shown) and the filling metal material layer (not shown) in each second recess 122 and each first recess 112 under each second recess 122. Then, a planarization process and a metal etching process are performed to form a top barrier metal layer 304 and a filling metal layer 306 in each second recess 122 and each first recess 112 under each second recess 122, thereby forming the first metal gate 308a and the second metal gate 308b. A top surface of the first metal gate 308a and a top surface of the second metal gate 308b are lower than a top surface of the ILD layer 106. Next, the insulating cover layers 134 are formed in the second recesses 122 respectively. Moreover, the following steps of this embodiment for forming the insulating layer 140, the contact plug opening 142 and the contact plug 144 are the same as the first embodiment, and will not be detailed redundantly.

In the first metal gate 308a and the second metal gate 308b of this embodiment, since each first recess 112 under each second recess 122 is not filled up after removing the first filling layers 118a, each formed top barrier metal layer 304 can has a like inverse Ω-shaped part respectively. Specifically, each top barrier metal layer 304 may has a U-shaped part 304a and two flat parts 304b, which forms a like inverse Ω shape. Each U-shaped part 304a is disposed between each pair of the wide parts 104a, and the flat parts 304b are disposed on the wide parts 104a and between each pair of the narrow parts 104b and extend from two ends of each U-shaped part 304a to be in contact with the narrow parts 104b respectively.

Refer to FIGS. 16-18, which are schematic diagrams illustrating a method for manufacturing a semiconductor device having a metal gate according to a fourth embodiment of the present invention. The difference between this embodiment and the third embodiment is that each first recess 112 is widened to be each second recess 122 after forming the first metal gate 402a and the second metal gate 402b in this embodiment. As shown in FIG. 16, the step of forming the second work function metal layer 302 and the steps before it in this embodiment are the same as the third embodiment, and will not be detailed redundantly. After forming the second work function metal layer 302, a top barrier metal material layer 404 and a filling metal material layer 406 are sequentially formed to fill up the first recesses 112 and followed by performing a planarization process and a metal etching process to form the second work function metal layers 302a, the top barrier metal layers 404a and filling layers 406a, thereby forming a first metal gate 402a and a second metal gate 402b. A top surface of the first metal gate 402a and a top surface of the second metal gate 402b are lower than a top surface of the ILD layer 106. In this embodiment, each filling layer 406a is a filling metal layer.

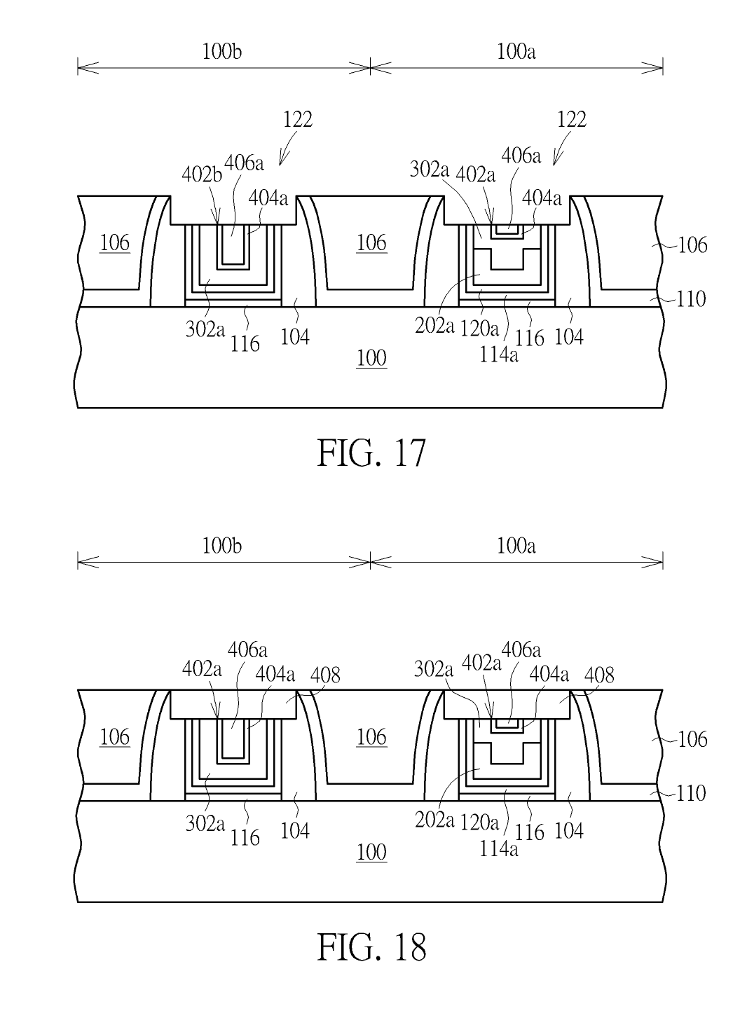

As shown in FIG. 17, after forming the first metal gate 402a and the second metal gate 402b, a first removing process is performed to widen each first recess 112 on the top surface of each filling layer 406a to be a second recess 122, such that each spacer 104 has a wide part 104a and a narrow part 104b. Each narrow part 104b is disposed on each wide part 104a, and each spacer 104 in each second recess 122 forms a step layout. Since the second recesses 122 are formed after the first metal gate 402a and the second metal gate 402b, the first metal gate 402a and the second metal gate 402b are not in contact with the narrow parts 104b.

As shown in FIG. 18, subsequently, an insulating cover layer 408 is directly formed in each second recess 122 respectively. It should be noted that the insulating cover layers 408 are formed right after forming each second recess 122, so that each second recess 122 is filled up with each insulating cover layer 408 and only filled with each insulating cover layer 408. Moreover, the following steps of this embodiment for forming the insulating layer 140, the contact plug opening 142 and the contact plug 144 are the same as the first embodiment, and will not be detailed redundantly.

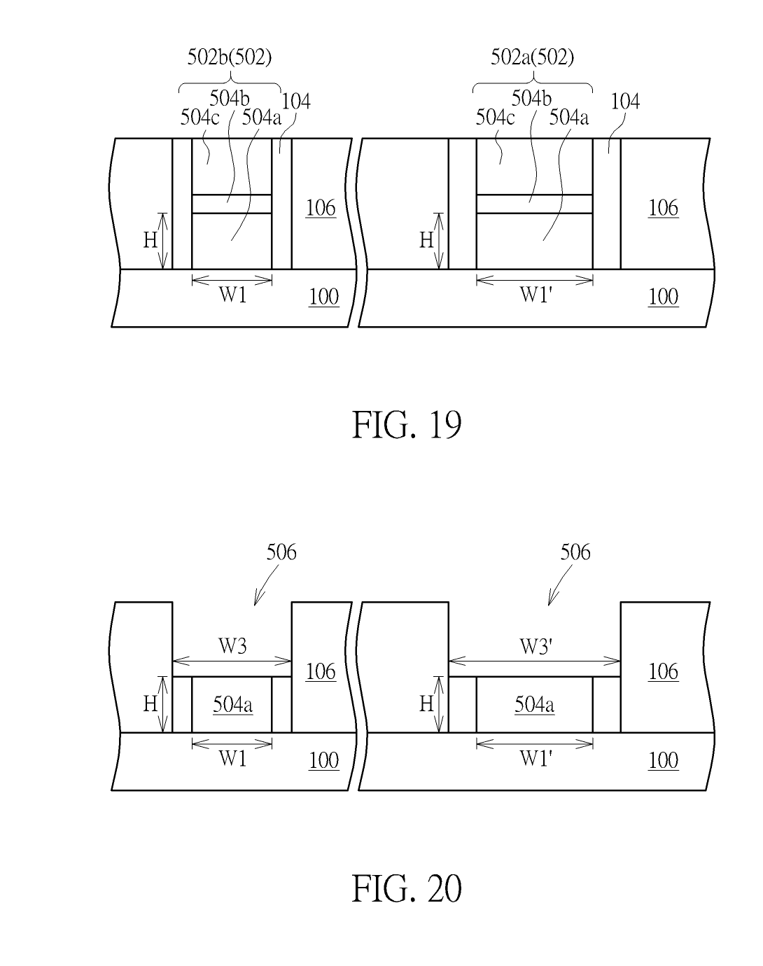

Refer to FIGS. 19-21, which are schematic diagrams illustrating a method for manufacturing a semiconductor device having a metal gate according to a fifth embodiment of the present invention. As shown in FIG. 19, as compared with the first embodiment, each dummy gate 502 provided in this embodiment include a multilayer structure formed by different materials stacked sequentially, and the different materials have different widths. In this embodiment, the dummy gates 502 can be divided into a first dummy gate 502a and a second dummy gate 502b, and a width W1′ of the first dummy gate 502a is larger than a width W1 of the second dummy gate 502b. Each dummy gate 502 can be formed by the following steps. A first material layer (not shown), a first hard mask material layer (not shown), a second material layer (not shown) and a second hard mask material layer (not shown) are sequentially formed on the substrate 100 first and followed by performing a photolithographic process and an etching process to pattern the first material layer, the first hard mask material layer, the second material layer and the second mask material layer, thereby forming a first dummy gate layer 504a, a second hard mask layer 504b, a second dummy gate layer 504c and a first hard mask layer (not shown) sequentially stacked on the substrate 100. After forming each dummy gate 502, a pair of spacers 104 are formed on sidewalls of each dummy gate 502 and then covered with the CESL (not shown) and the ILD layer 106 sequentially. Thereafter, a planarization process is performed to remove the first hard mask layer and expose each second dummy gate layer 504c. It should be noted that the first dummy gate 502a and the second dummy gate 502b have different widths W1′, W1 in this embodiment, and the first dummy gate 502a and the second dummy gate 502b are formed by the photolithographic process and the etching process, so that the first dummy gate layer 504a of the first dummy gate 502a and the first dummy gate layer 504a of the second dummy gate 502b have a same thickness H. For instance, the thickness H of the first dummy gate layer 504a may be substantially 300 Å.

As shown in FIG. 20, after exposing the second dummy gate layer 504c, the second dummy gate layer 504c is removed to form a third recess (not shown) between each pair of spacers 104. It should be noted that the first dummy gate layer 504a will not be damaged during removing the second dummy gate layer 504c due to the shielding of the first hard mask layer 504b. Accordingly, the first dummy gate layer 504a of the first dummy gate 502a and the first dummy gate layer 504a of the second dummy gate 502b can still have the same thickness H after removing the second dummy gate layer 504c. Next, the first hard mask layer 504b is removed and followed by removing the spacers 104 on the top surface of each first dummy gate layer 504a to widen each third recess to form a fourth recess respectively through a high etching selectivity ratio for etching the spacers 104 relative to the first dummy gate layer 504a. In another variant, the second hard mask layer may be removed after forming each fourth recess.

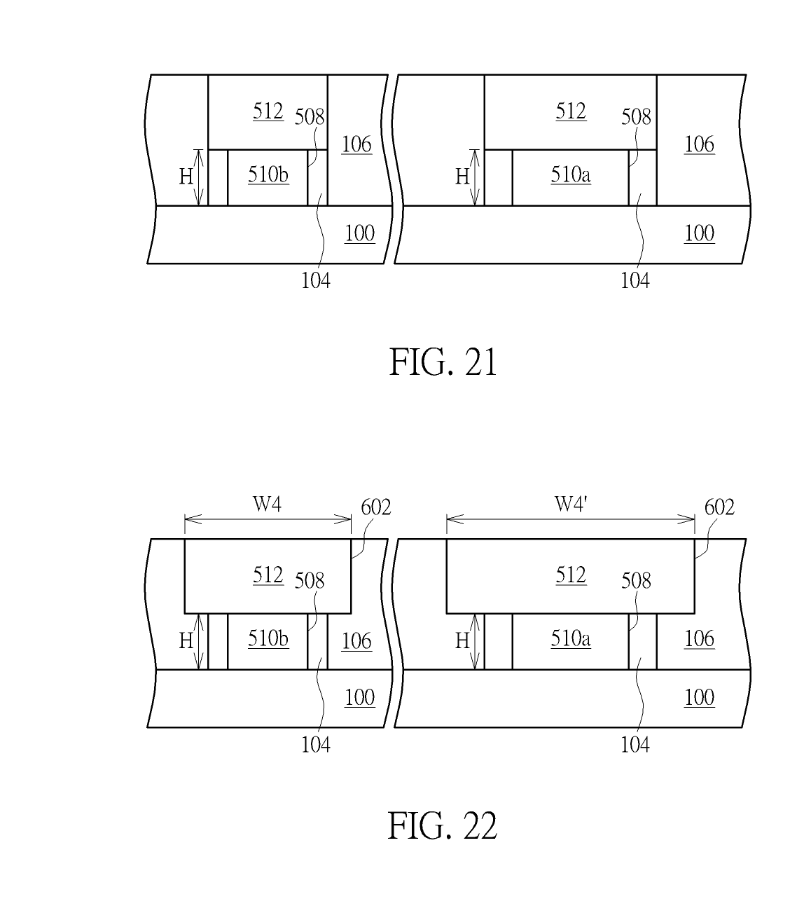

As shown in FIG. 21, subsequently, the first dummy gate layer 504a is removed fully to form a fifth recess 508 under each fourth recess 506 respectively and followed by forming a first metal gate 510a and a second metal gate 510b in the fifth recesses 508 respectively. Since the first dummy gate 502a and the second dummy gate 502b have different widths W1′, W1, the formed fifth recesses 508 also have different width W1′, W1 respectively, and the first metal gate 510a and the second metal gate 510b also have different widths W1′, W1 respectively. Preferably, a top surface of the first metal gate 510a and a top surface of the second metal gate 510b are leveled with a bottom surface of each fourth recess 506. Next, each fourth recess 506 is filled with an insulating cover layer 512. Preferably, each fourth recess 506 is filled up with each insulating cover layer 512, and a top surface of each insulating cover layer 512 is leveled with the top surface of the ILD layer 106.

It should be noted that since the widths W3, W3′ of the fourth recesses 506 are larger than the widths W1, W1′ of the fifth recesses 508 respectively, the widths W3, W3′ of the insulating cover layers 512 filling into the fourth recesses 506 respectively are larger than the width W1′ of the second metal gate 510b and the width W1 of the first metal gate 510a respectively. Accordingly, the insulating cover layers 512 can effectively protect the first metal gate 510a and the second metal gate 510b. Also, the thickness H of the first dummy gate layer 504a can be maintained during widening the third recesses through forming the second hard mask layer 504b between the first dummy gate layer 504a and the second dummy gate layer 504c. Thus, the formed fifth recesses 508 can have different widths but the same height, and the formed first metal gate 510a and the formed second metal gate 510b have different widths but the same thickness.

Refer to FIG. 22, which is a schematic diagram illustrating a method for manufacturing a semiconductor device having a metal gate according to a sixth embodiment of the present invention. As shown in FIG. 22, as compared with the fifth embodiment, the step of widening each third recess further includes removing a part of the ILD layer 106 on the top surface of the first dummy gate layer 504a in this embodiment, such that the widths W4, W4′ of the fourth recesses 602 of this embodiment are larger than the widths W3, W3′ of the fourth recesses 506 of the fifth embodiment respectively. Since the step of removing the first hard mask layer 504b and the steps thereafter are the same as the fifth embodiment, and will not be detailed redundantly. In another variant, the step of forming the fourth recesses may only remove a part of CESL on the top surface of the first dummy gate layer, and the contact surface between the ILD layer and the CESL is not exposed.

In summary, in the method for manufacturing the semiconductor device having the metal gate provided by the present invention, the layers needed to be filled into the first recess, such as the high-K gate dielectric layer, the bottom barrier metal layer, the first work function metal layer, the second work function metal layer and the top barrier metal layer, are formed in the first recess that is filled with the filling layer, and the first recess on the filling layer is widened before removing the filling layer, so that the following steps for filling the layers into the first recess will not result in the bad filling problem.

Those skilled in the art will readily observe that numerous modifications and alterations of the device and method may be made while retaining the teachings of the invention. Accordingly, the above disclosure should be construed as limited only by the metes and bounds of the appended claims.

1. A method for manufacturing a semiconductor device having a metal gate, comprising:
providing a substrate, a pair of spacers and an interlayer dielectric layer, wherein the spacers and the interlayer dielectric layer are formed on the substrate, the interlayer dielectric layer surrounds the spacers, and the spacers have a first recess therebetween;
forming a high dielectric constant (high-K) dielectric layer on a surface of the first recess, top surfaces of the spacers and a top surface of the interlayer dielectric layer;
forming a sacrificial layer on the high-K dielectric layer, wherein the first recess is filled up with the sacrificial layer;
performing a second removing process to remove the sacrificial layer outside the first recess and a part of the sacrificial layer in the first recess, thereby forming a filling layer in the first recess;
performing a third removing process to remove the high-K dielectric layer on the top surface of the filling layer, thereby forming a high-K gate dielectric layer in the first recess, wherein the high-K gate dielectric layer and the filling layer are sequentially stacked in the first recess, and an exposed top surface of the high-K gate dielectric layer and a top surface of the filling layer are lower than a top surface of the interlayer dielectric layer;
performing a first removing process to remove a part of each spacer disposed on the top surface of the filling layer and to widen the first recess on the top surface of the filling layer, thereby forming a second recess, wherein a width of the second recess is larger than a width of the first recess;
performing a fourth removing process to remove the filling layer; and
forming the metal gate in the second recess and the first recess under the second recess, wherein forming the metal gate comprises:
forming a first work function metal layer in the second recess and the first recess under the second recess; and
forming a second work function metal layer and a filling metal layer on the first work function metal layer, wherein the second work function metal layer is disposed between the first work function metal layer and the filling metal layer, and the first work function metal layer and the second work function metal layer comprise different metals with different work functions for transistors of different types respectively.

2-3. (canceled)

4. The method for manufacturing the semiconductor device having the metal gate according to claim 1, further comprising forming an insulating cover layer on the metal gate.

5-12. (canceled)

13. A semiconductor device having a metal gate, comprising:
a substrate;
a pair of spacers, disposed on the substrate, each spacer having a wide part and a narrow part on the wide part, wherein a gap spaced between the narrow parts is larger than a gap spaced between the wide parts;
a high-K gate dielectric layer, disposed on the substrate and between the spacers;
a metal gate, disposed on the high-K gate dielectric layer, the metal gate comprising a first work function metal layer, a second work function metal layer and a filling metal layer sequentially stacked on the high-K gate dielectric layer, wherein the first work function metal layer and the second work function metal layer comprise different metals with different work functions for transistors of different types respectively, the first work function metal layer comprises a U-shaped part and two flat parts, the U-shaped part is disposed between the wide parts, the flat parts are disposed on the wide parts and between the narrow parts, and the flat parts extend form two ends of the U-shaped part to be in contact with the narrow parts respectively;
an insulating cover layer, disposed on the metal gate; and
an interlayer dielectric layer, disposed on the substrate, and the interlayer dielectric layer surrounding the metal gate, the spacers and the insulating cover layer.

14-15. (canceled)

16. The semiconductor device having the metal gate according to claim 13, wherein the metal gate further comprises a filling metal layer, disposed between the first work function metal layer and the insulating cover layer.

17. The semiconductor device having the metal gate according to claim 13, wherein the metal layer further comprises a top barrier metal layer.

18-20. (canceled)
